(19) United States
(12) Patent Application Publication
(10) Pub. No.: US 2009/0290301 A1
(43) Pub. Date: Nov. 26, 2009

(54) HEAT SINK FOR AN ELECTRONIC DEVICE

(76) Inventors: Anton Legen, Munich (DE); Lutz Morgenroth, Munich (DE)

Correspondence Address: PATTERSON & SHERIDAN, LLP;Gero McClellan / Qimonda, 3040 POST OAK BLVD.,, SUITE 1500, HOUSTON, TX, 77056, US

(21) Appl. No.: 12/126,183

(22) Filed: May 23, 2008

(51) Int. Cl. H05K 7/20

(52) U.S. Cl. 361/679.54; 361/711

(57) ABSTRACT

An electronic device with a clip and a plate of thermally conductive material is disclosed. A first surface of the plate is attached to a surface of the electronic device. The clip is arranged on a second surface of the plate. Two ends of the clip clasp the electronic device and the plate at opposed edges of the electronic device, pressing the plate to the electronic device.

### FIELD OF THE INVENTION

The present invention relates to an electronic device, to a heat sink plate for an electronic device, to a memory module, and to an electronic system.

### BACKGROUND OF THE INVENTION

Due to the ongoing miniaturization of electronic devices, their increased density and the increase of clock frequencies, modern electronic devices produce more and more heat per surface area. In order to prevent a thermal degradation and destruction, the requirements for cooling these electronic devices have increased over the last years. In today's powerful computers even a cooling of memory modules is required.

At present, memory modules are available in various forms, as e.g. SIMMs (Single Inline Memory Module), DIMMs (Dual Inline Memory Module), or RIMMs (RAMBUS Inline Memory Modules). Despite technological differences, all these memory modules follow a principally similar design. A memory module includes a plurality of integrated memory chips which are placed on a printed circuit board designed as a plug-in card. The printed circuit board provides conductive paths to connect the memory chips with contact pads provided at one edge of the printed circuit board. The printed circuit board can for example be plugged into a memory slot of a computer's main board. On the memory module, the integrated memory chips are arranged in such a way that their longitudinal direction is perpendicular to the insertion direction of the memory module. Along with the integrated memory chips, a memory module may also include one or more auxiliary chips like buffer chips, register chips and PLL chips. Both the integrated memory chips and the auxiliary chips may produce an amount of heat during operation that may make cooling necessary. The auxiliary chips may produce more heat than the memory chips.

### SUMMARY OF THE INVENTION

One embodiment of an electronic device provides a clip and a plate of thermally conductive material. A first surface of the plate is attached to a surface of the electronic device. The clip is arranged on a second surface of the plate. Two ends of the clip clasp the electronic device and the plate at opposed edges of the electronic device, pressing the plate to the electronic device.

A heat sink provides a plate for an electronic device according to one embodiment. The heat sink plate includes a thermally conductive material. A first surface of the heat sink plate can be pressed to a surface of the electronic device. The heat sink plate is at least partially corrugated in a direction perpendicular to the first surface of the heat sink plate.

A memory module provides a clip and a plate of thermally conductive material according to one embodiment. A first surface of the plate is attached to a surface of the memory module. The clip is arranged on a second surface of the plate. Two ends of the clip clasp the memory module and the plate at opposed edges of the memory module, pressing the plate to the memory module.

An electronic system provides a memory module with a clip and a plate of thermally conductive material according to one embodiment. A first surface of the plate is attached to a surface of the memory module. The clip is arranged on a second surface of the plate. Two ends of the clip clasp the memory module and the plate at opposed edges of the memory module, pressing the plate to the memory module.

A heat sink provides a plate for a memory module according to one embodiment. The heat sink plate includes a thermally conductive material. A first surface of the heat sink plate can be pressed to a surface of the memory module. The heat sink plate is corrugated in a direction perpendicular to the first surface of the heat sink plate.

A electronic system provides a memory module with a heat sink plate according to one embodiment. The heat sink plate includes a thermally conductive material. A first surface of the heat sink plate can be pressed to a surface of the memory module. The heat sink plate is at least partially corrugated in a direction perpendicular to the first surface of the heat sink plate.

### BRIEF DESCRIPTION OF THE DRAWINGS

So that the manner of which the above recited features can be understood in detail, a more particular description of the invention, briefly summarized above, may be had by referenced embodiments, some of which are illustrated in the appending drawings. It is to be noted, however, that the appended drawings illustrate only typical embodiments of this invention and are therefore not to be considered limiting of the scope, for the invention may admit to other equally effective embodiments.

FIG. 1 shows a schematic representation of an electronic device with a heat sink;

FIG. 2 shows a sectional drawing of a heat sink plate;

FIG. 3 shows a sectional drawing of a heat sink plate;

FIG. 4 shows a schematic representation of an electronic device with a heat sink;

FIG. 5 shows a schematic representation of an electronic device with a heat sink;

FIG. 6 shows a schematic representation of an electronic device with a heat sink;

FIG. 7 shows a sectional drawing of a clip for a heat sink;

FIG. 8 shows a sectional drawing of a clip for a heat sink;

FIG. 9 shows a schematic representation of a heat sink plate;

FIG. 10 shows a schematic representation of a clip for a heat sink;

FIG. 11 shows a schematic representation of a heat sink plate.

### DETAILED DESCRIPTION OF THE PREFERRED EMBODIMENT

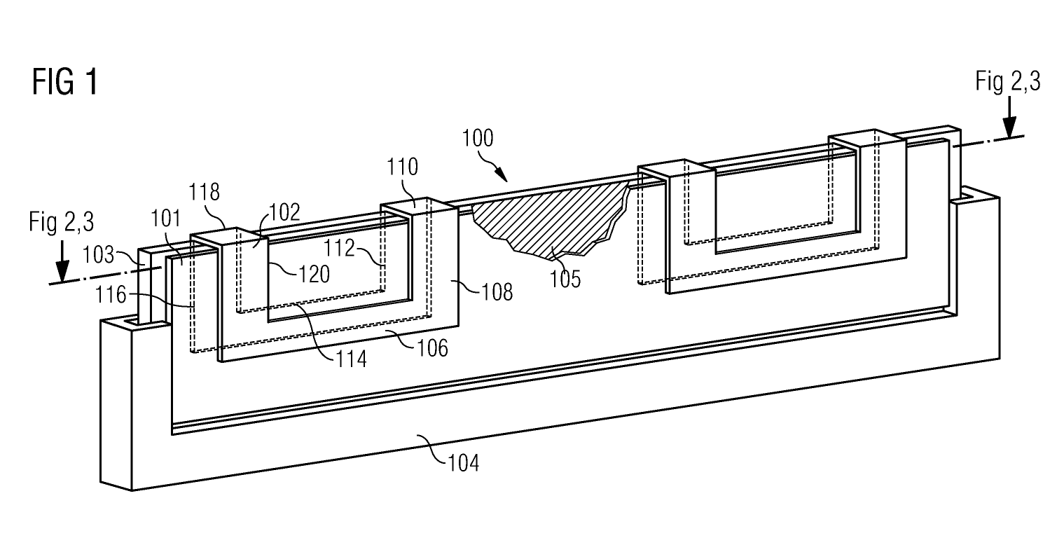

FIG. 1 shows a schematic representation of an electronic device with a heat sink according to one embodiment. The electronic device may for example be a memory module 103, for example a DIMM (Dual Inline Memory Module). The electronic device may as well be another kind of electronic device. The memory module 103 may include a printed circuit board of flat rectangular shape. Integrated memory chips may be arranged on one or both sides of the printed circuit board. Along one of the long edges of the printed circuit board of the memory module 103, contact pads are arranged to provide an electric connection to the memory chips arranged on the printed circuit board of the memory module 103. The memory module 103 may also include further integrated circuits like buffer chips, register chips, or PLL chips.

The memory module 103 shown in FIG. 1 is plugged into a slot 104. The slot 104 electrically connects the contact pads of the memory module 103 to further electronic components. The slot 104 may for example connect the memory module 103 to a printed circuit board of a computer. The slot 104 includes a receptacle that is at least the length of a longer edge of the memory module 103. The receptacle of the slot 104 includes two parallel jaws that receive the long edge of the memory module 103 that includes contact pads. The receptacle of the slot 104 provides electric contact between the contact pads of the memory module 103 and other electronic components of the computer. On both ends of the receptacle of the slot 104 poles may be provided to further support the memory module 103. The poles of the slot 104 are arranged perpendicular to the receptacle of the slot 104. The poles may partially embrace the two shorter edges of the flat rectangular memory module 103 between two parallel jaws.

FIG. 1 further shows a heat sink 100 attached to the memory module 103 according to one embodiment. The heat sink 100 includes a plate 101. The plate 101 is made of a thermally conductive material. The material of the plate 101 may for example include aluminum, copper or graphite. The plate 101 may as well include another material with high thermal conductivity. The plate 101 may include a flat rectangular shape of approximately the same size as the memory module 103. The plate 101 may as well comprise another shape. The plate 101 is arranged in parallel to the memory module 103. A first surface of the plate 101 is at least partially in contact with a first surface of the memory module 103, thereby being in contact with one or more integrated chips arranged on the first surface of the memory module 103.

In order to achieve an effective cooling of the memory module 103, a high contact pressing force between the heat sink plate 101 and the memory module 103 may be applied. The contact pressing force may be uniform over the entire surface of the memory module 103. If the memory module 103 includes strong heat sources like buffer chips or register chips, however, an elevated contact pressing force between the heat sources and the heat sink plate 101 may be advantageous.

In the embodiment of the heat sink 100 shown in FIG. 1, two clips 102 are provided to hold the plate 101 of the heat sink 100 in contact with the memory module 103. There may also be fewer or more than two clips 102. Each clip 102 may be fabricated from a metal sheet. A clip 102 may for example be fabricated from a sheet of spring steel.

According to the embodiment shown in FIG. 1, the clip 102 has the shape of a flat rectangular frame with four boarders enclosing an open area. This rectangular frame is folded twice by 90° around two axes that are parallel to two boarders of the rectangular frame and perpendicularly cut the other two boarders of the rectangular frame close to the centers of these other two boarders of the frame. This results in a clip 102 with the shape of a saddle. From two perpendicular directions, the clip 102 may be in the shape of the letter U.

The clips 102 may be attached to the memory module 103 and the plate 101 on one edge of the memory module 103. Both clips 102 may be attached to the long edge of the memory module 103 that is opposite the edge of the memory module 103 that is plugged into the slot 104. Each clip 102 clasps around the memory module 103 and the plate 101 such that one half of the U-shaped clip 102 is arranged on the second surface of the plate 101 that is opposite the first surface of the plate 101 that is in contact with the memory module 103. The other half of the U-shaped clip 102 is arranged on the second surface of the memory module 103 that is opposite the first surface of the memory module 103 that is in contact with the plate 101.

A first strip 106 of the clip 102 is arranged parallel to the longer edges of the memory module 103 on the second surface of the plate 101. A second strip of the clip 102 is connected to the first strip of the clip 102 at an angle of ninety degrees. The second strip 108 of the clip 102 is arranged parallel to the shorter edges of the memory module 103 on the second surface of the plate 101 and reaches the longer edge of the memory module 103 that is opposite the long edge of the memory module 103 that includes contact pads. A third strip 110 of the clip 102 is connected to the second strip of the clip 102 at an angle of ninety degrees. The third strip of the clip 102 runs from the second surface of the plate 101 to the second surface of the memory module 103. A fourth strip 112 (shown in phantom) of the clip 102 is connected to the third strip of the clip 102 at an angle of ninety degrees. The fourth strip of the clip 102 is arranged parallel to the shorter edges of the memory module 103 on the second surface of the memory module 103 and runs towards the edge of the memory module 103 that includes contact pads. A fifth strip 114 (shown in phantom) of the clip 102 is connected to the fourth strip of the clip 102 at an angle of ninety degrees. The fifth strip of the clip 102 is arranged parallel to the longer edges of the memory module 103 on the second surface of the memory module 103. A sixth strip 116 (shown in phantom) of the clip 102 is connected to the fifth strip of the clip 102 at an angle of ninety degrees. The sixth strip of the clip 102 is arranged parallel to the shorter edges of the memory module 103 on the second surface of the memory module 103 and reaches the longer edge of the memory module 103 that is opposed to the long edge of the memory module 103 that includes contact pads. A seventh strip 118 of the clip 102 is connected to the sixth strip of the clip 102 at an angle of ninety degrees. The seventh strip of the clip 102 runs from the second surface of the memory module 103 to the second surface of the plate 101. An eighth strip of the clip 102 is connected to the seventh strip of the clip 102 at an angle of ninety degrees and to the first strip of the clip 102 at an angle of ninety degrees. The eighth strip 120 of the clip 102 is arranged parallel to the shorter edges of the memory module 103 on the second surface of the plate 101 and runs towards the edge of the memory module 103 that includes contact pads.

The clip 102 applies a contact pressing force to the plate 101 and the memory module 103, pressing the plate 101 and the memory module 103 together.

According to another embodiment of the present invention, the heat sink 100 may include two plates 101 arranged on both surfaces of the memory module 103. The first heat sink plate 101 is pressed to a first surface of the memory module 103. The second heat sink plate 101 is pressed to a second surface of the memory module 103 that is opposed to the first surface of the memory module 103. In this embodiment of the present invention, the clip 102 claps around both plates 101, pressing the two plates 101 to both sides of the memory module 103.

The number of clips 102 of the heat sink 100 is not limited to two. Fewer or more clips 102 may be provided. The clips 102 may be arranged next to each other on the same edge of the memory module 103. The clips 102 may also be arranged on different edges of the memory module 103. The heat sink 100 may for example include three clips 102 arranged on the long edge of the memory module 103 that is opposed to the edge of the memory module 103 that is plugged into the slot 104.

Between the plate 101 and the memory module 103 a thermal interface material 105 may be provided to improve the thermal contact between the memory module 103 and the plate 101. The thermal interface material 105 may be a heat conducting pad or a heat conducting paste. The thermal interface material 105 may include an elastomer. The thermal interface material 105 lies thinly and evenly between the memory module 103 and the plate 101 according to one embodiment. If the heat sink 100 includes two plates 101 arranged on both sides of the memory module 103, a thermal interface material 105 may be provided between the memory module 103 and one or both heat sink plates 101.

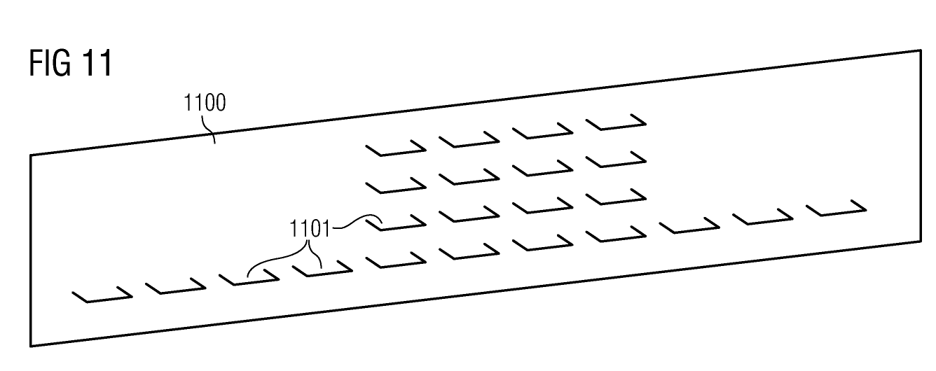

FIG. 11 shows an alternative embodiment of a heat sink plate 1100. The surface of the plate 1100 that is opposed to the surface of the plate 1100 that is in contact with the memory module 103 includes a plurality of cooling fins 1101. The cooling fins 1101 may be made of the same material as the plate 1100. The cooling fins 1101 may be arranged on the plate 1100 at an angle of ninety degrees relative to the plate surface on which they are disposed. The cooling fins 1101 may be provided to increase the surface area of the plate 1100. The cooling fins 1101 may be provided in areas of the surface of the plate 1100 that are not in contact with a clip 102.

The memory module 103 in FIG. 1 may include a plurality of integrated chips arranged on one or both surfaces of the memory module 103. These chips may for example be memory chips, register chips, buffer chips, or PLL chips. Some of the integrated chips provided on the memory module 103 may produce more heat than other integrated chips provided on the memory module 103. An increased contact pressing force between the plate 101 and the memory module 103 may be provided at the locations of the integrated chips that produce a larger amount of heat. An elevated contact pressing force between the plate 101 and the memory module 103 may be achieved by preforming the plate 101 as explained below. This may provide a high contact pressing force between the plate 101 and the memory module 103 independent of the position of the clip 102.

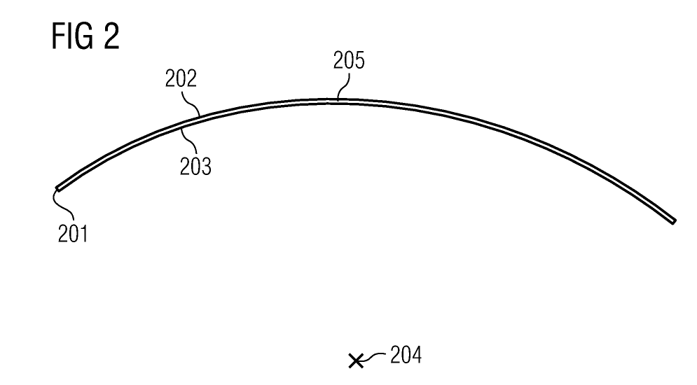

FIG. 2 shows a sectional view of a plate 201 of a heat sink 100. For the sectional view of FIG. 2, the plate 201 is sliced on a plane that is perpendicular to the two surfaces of the plate 201 and parallel to the two longer edges of the plate 201. The plate 201 includes a first surface 202 that may be pressed to a memory module 103. The plate 201 includes a second surface 203 that is opposed to the first surface 202.

The plate 201 depicted in FIG. 2 is preformed. The plate 201 is bent around an axis 204 that is parallel to the two shorter edges of the plate 201. The axis 204 points out of the drawing plane of FIG. 2. The first surface 202 of the plate 201 is concave. The second surface 203 of the plate 201 is convex. If the first surface 202 of the plate 201 is pressed to a surface of a memory module 103, the bending of the plate 201 may partially be equalized by bending the plate 201 back into a more flat arrangement. This may result in an elevated contact pressing force between the surface 203 of the plate 201 and the memory module 103 in a central area 205 of the plate 201. This may be advantageous if the center of the memory module 103 includes a chip that produces more heat than the other chips on the memory module 103. If the plate 201 is bent around another axis than the axis 204, an elevated contact pressing force between the surface 203 of the plate 201 and the memory module 103 in another area of the plate 201 than the central area 205 of the plate 201 may be achieved. This may be advantageous if the other area of the memory module 103 (e.g., other than the center of the memory module 103) includes a chip that produces more heat than the other chips on the memory module 103.

The central area 205 of the plate 201 may be protruded over the two shorter edges of the plate 201 by 0% to 10% of the length of the long edges of the plate 201. According to another embodiment the central area 205 of the plate 201 may be protruded over the two shorter edges of the plate 201 by 10% to 20% of the length of the long edges of the plate 201. According to another embodiment the central area 205 of the plate 201 may be protruded over the two shorter edges of the plate 201 by 20% to 40% of the length of the long edges of the plate 201.

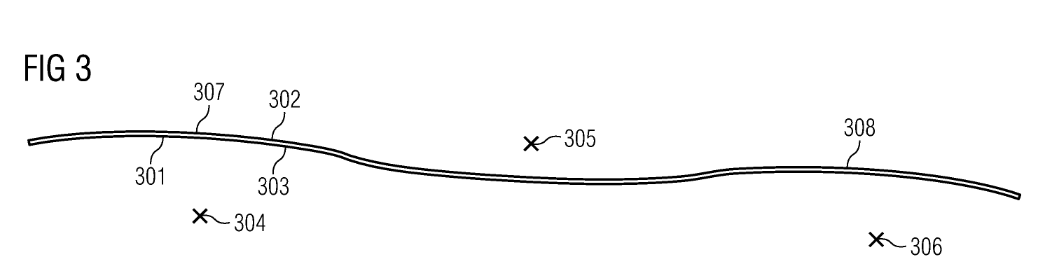

FIG. 3 shows a sectional view of another plate 301 of a heat sink 100. In the sectional view of FIG. 3, the plate 301 is sliced on a plane that is parallel to the two longer edges of the plate 301 and perpendicular to the two surfaces of the plate 301. The plate 301 includes a first surface 302 that may be pressed to a surface of a memory module 103.

The plate 301 includes a second surface 303 that is opposite the first surface 302.

The plate 301 is bent around three axes 304, 305, 306 that are parallel to the two shorter edges of the plate 301. The axes 304, 305, 306 point out of the drawing plane of FIG. 3. This results in a corrugation of the plate 301, for example in a sinusoidal sectional shape of the plate 301. If the first surface 302 of the plate 301 is pressed to a surface of a memory module 103, the plate 301 will provide an elevated contact pressing force between the plate 301 and the surface of the memory module 103 in two sections 307, 308 of the plate 301. This may be advantageous if the memory module 103 includes two chips that produce a larger amount of heat than the other chips on the memory module 103 and these chips are located in the sections of the memory module 103 where an elevated contact pressing force is applied.

The amplitude of the corrugation of the plate 301 may be between 0% and 10% of the length of the long edges of the plate 301. According to another embodiment, the amplitude may be between 10% and 20% of the length of the long edges of the plate 301. According to another embodiment, the amplitude may be between 20% and 40% of the length of the long edges of the plate 301.

The preformed plates 201, 301 of FIGS. 2 and 3 show only two possible profiles for preformed plates for heat sinks 100. The plate of the heat sink may also include a swelling. The plate of the heat sink may be thicker in sections of the plate where an elevated contact pressing force between the plate and the memory module 103 is desired. The plate of the heat sink may include a bump on a surface of the plate that does not reach from one edge of the plate to the opposite edge of the plate. The plate of the heat sink may include an embossing. According to the present invention, the plate of a heat sink 100 may be preformed to any shape that is suitable to provide an elevated contact pressing force between the plate and the memory module 103 in certain sections of the surface of the memory module 103. The plate of the heat sink 100 may for example provide elevated contact pressing forces in three sections of the surface of the memory module 103.

The plates 201, 301 shown in FIG. 2 and 3 may be mounted to a memory module 103 with one or more clips 102 as shown in FIG. 1. The plates 201, 301may as well be mounted to a memory module 103 with another kind of clips.

The surface 202 of the plate 201 shown in FIG. 2, and the surface 302 of the plate 301 shown in FIG. 3 may include a plurality of cooling fins as shown in FIG. 11 and described before. The cooling fins may be provided to increase the surface areas of the surfaces 202, 203 of the plates 201, 301 respectively. The cooling fins may be provided in areas of the surfaces 202, 203 of the plates 201, 301 that are not in contact with clips. The cooling fins may be subdivided to allow for a bending of the plates 201, 301. The cooling fins may also stiffen the plates 201, 301 to increase the contact pressing forces induced by the plates 201, 301.

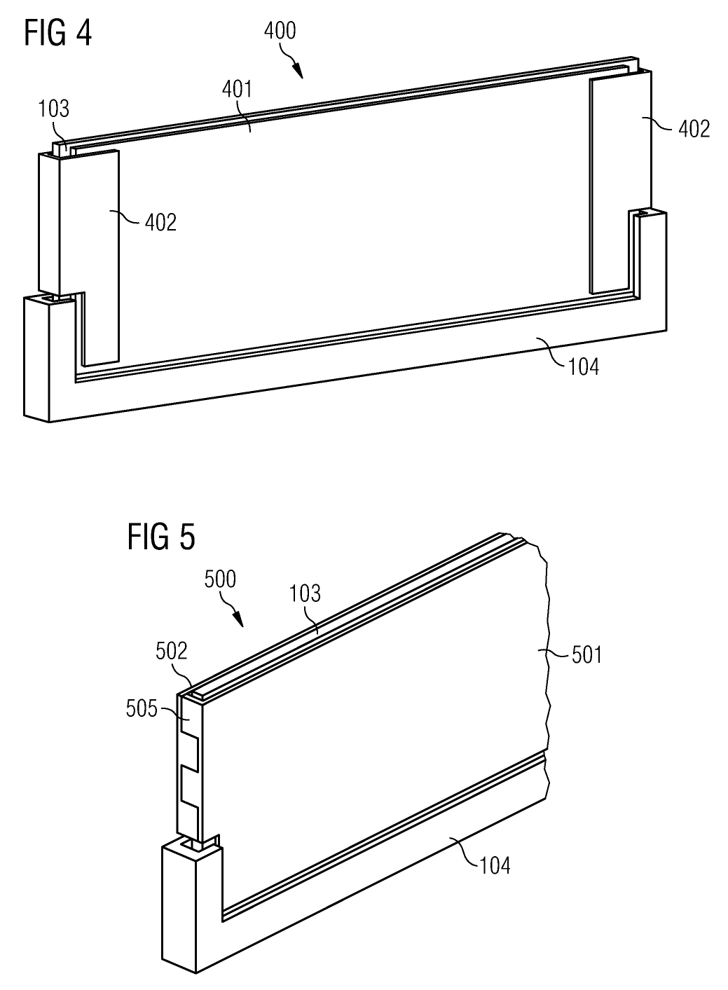

FIG. 4 shows a heat sink 400 according to an alternative embodiment. The heat sink 400 includes a plate 401 that may be pressed to a memory module 103 with clips 402. The memory module 103 is plugged into a slot 104. The plate 401 may be preformed as the plates 201, 301 shown in FIG. 2 and 3. One surface of the plate 401 is pressed to a surface of the memory module 103.

The plate 401 may be made of a material with high thermal conductivity. The material of the plate 401 may comprise aluminum, copper, and/or graphite. The plate 401 may also comprise another material with high thermal conductivity.

The plate 401 may be pressed to the memory module 103 with two clips 402 that may be attached to two shorter edges of the memory module 103. The clips 402 may be made of spring steel. The clips 402 may be fabricated from a sheet of the clip material. The clips 402 may be fabricated from a rectangular sheet metal plate that is bent twice such that the resulting clip 402 is in the shape of the letter U. Each clip 402 may clasp around an edge of the plate 401 and an edge of the memory module 103 such that the plate 401 is pressed to the memory module 103 by the clip 402.

The heat sink 400 may as well include two plates 401 arranged on both sides of the memory module 103. In this case, the clip 402 clasps around both plates, pressing them to both sides of the memory module 103. Both plates 401 may be preformed as the plates 201, 301 shown in FIGS. 2, 3. In another embodiment only one plate 401 or none of the plates 401 are preformed.

Depending on the length of the shorter edge of the memory module 103, the clips 402 shown in FIG. 4 may be advantageous over the clips 102 shown in FIG. 1. If the shorter edges of the memory module 103 are too long, the clips 102 of FIG. 1 may not be sufficient to provide a large enough contact pressing force between the plate 401 and the memory module 103 in an area of the memory module 103 close to the edge of the memory module 103 that is plugged into the slot 104. The clips 402 shown in FIG. 4, however, may provide a more constant contact pressing force between the plate 401 and the memory module 103 in the entire region of the surface of the memory module 103 between the first longer edge of the memory module 103 and the second longer edge of the memory module 103. It is also contemplated that a combination of the clips 102 of FIG. 1 and the clips 402 of FIG. 4 are used for a given memory module.

FIG. 5 shows a schematic representation of another embodiment of a heat sink 500. The heat sink 500 may be used to lead off heat from a memory module 103. The heat sink 500 includes a first plate 501 and a second plate 502. A first surface of the first plate 501 is pressed to a first surface of a memory module 103. A first surface of the second plate 502 is pressed to a second surface of the memory module 103.

The memory module 103 may be in a basically flat rectangular shape. Semiconductor chips are arranged on one or both surfaces of the memory module 103. These semiconductor chips may for example be memory chips, buffer chips, register chips, PLL chips, or other semiconductor chips. Metallic contact pads are arranged along one of the longer edges of the memory module 103 to provide electrical connections to the integrated chips on the memory module 103. This longer edge of the memory module 103 is plugged into a slot 104 that provides electric contact between the contact pads of the memory module 103 and other electric components.

The heat sink 500 shown in FIG. 5 does not include a clip. The plates 501, 502 each include at least one hook 505 or a plurality of hooks 505 arranged on both shorter edges of the plates 501, 502. The hooks 505 are arranged perpendicular to the plane of the plates 501, 502. The first and second plates 501, 502 may be fastened together with the hooks 505. The first and second plates 501, 502 clasp around the memory module 103 such that a first surface of the first plate 501 is pressed to a first surface of the memory module 103 and a first surface of the second plate 502 is pressed to a second surface of the memory module 103. The two plates 501, 502 are fixed together with the hooks 505 arranged on each shorter edge of the two plates 501, 502. This arrangement provides a contact pressing force between the plates 501, 502 and the memory module 103 but does not require an additional clip.

The first and second plates 501, 502 may be preformed as shown in FIGS. 2 and 3 to provide elevated contact pressing forces in designated regions of the surface of the memory module 103.

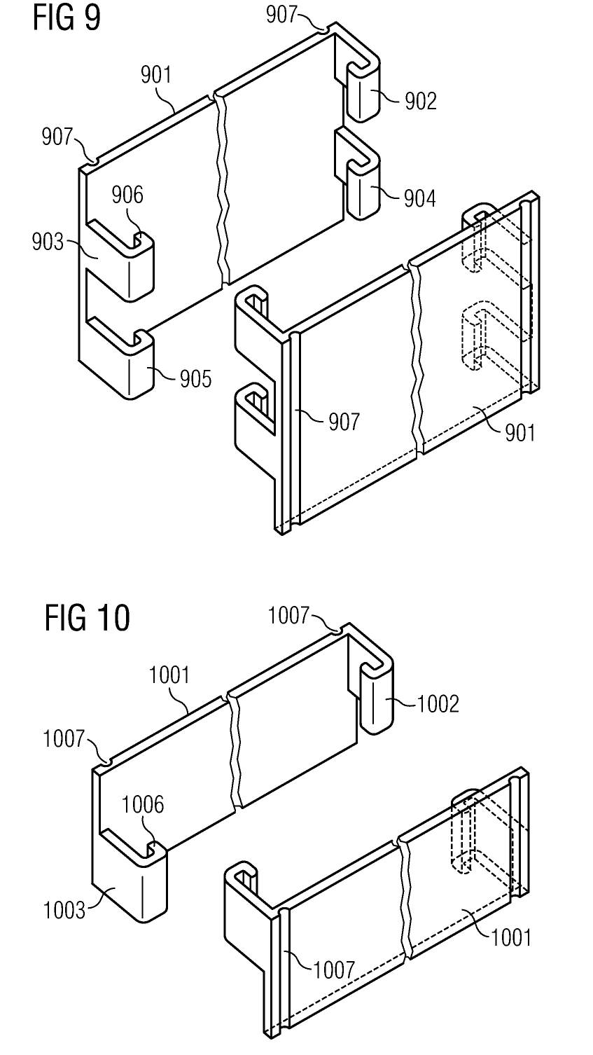

A possible embodiment of plates 501, 502 with hooks 505 is shown in FIG. 9. FIG. 9 depicts two plates 901 that may be used as heat sink plates. Each plate 901 is of essentially flat rectangular shape. Each plate 901 includes a first surface that may be pressed to a surface of a memory module and a second surface that is opposed to the first surface of the plate 901.

Each plate 901 includes four hooks 902, 903, 904, 905 that are arranged on the first surface of the plate 901 to point in a first direction perpendicular to the plane of the plate 901. The hooks 902, 904 are arranged along a first of the two shorter edges of the plate 901. Two other hooks 903, 905 are arranged along the second shorter edge of the plate 901. All four hooks 902, 903, 904, 905 point in the same first direction perpendicular to the plane of the plate 901.

For purpose of illustration only, the plate 901 is shown divided into four strips of similar height in the direction of the shorter edges of the plate 901. The hook 902 is arranged on the first strip that is arranged along a first long edge of the plate 901. The hook 903 is arranged on the second strip. The hook 904 is arranged on the third strip. The hook 905 is arranged on the fourth strip that is arranged along a second long edge of the plate 901. The plate 901 is symmetrical with respect to a rotation by 180° around an axis that is perpendicular to the plate of the plane 901 and intersects the center of the plane of the plate 901.

The second surface of each plate 901 includes two grooves 907. The grooves 907 are arranged parallel to the two shorter edges of the plate 901. The grooves 907 are arranged near the two shorter edges of the plate 901. One groove 907 is arranged near the first shorter edge of the plate 901. The other groove 907 is arranged near the second shorter edge of the plate 901.

The two identical plates 901 of FIG. 9 may be clipped together. The hooks 902, 903, 904, 905 of each plate 901 are staggered such that the hooks 902, 903, 904, 905 of the first plate 901 and the hooks 902, 903, 904, 905 of the second plate 901 may mesh with each other. Each hook of one plate 901 may clasp around the shorter edge of the respective other plate 901.

The tip of each hook 902, 903, 904, 905 is bent towards the center of the plate 901 and includes a flange 906 that points towards the first surface of the plate 901. The flange 906 of each hook 902, 903, 904, 905 of a first plate 901 can snap in a groove 907 of the second plate 901, thereby fixing the two plates 901 together.

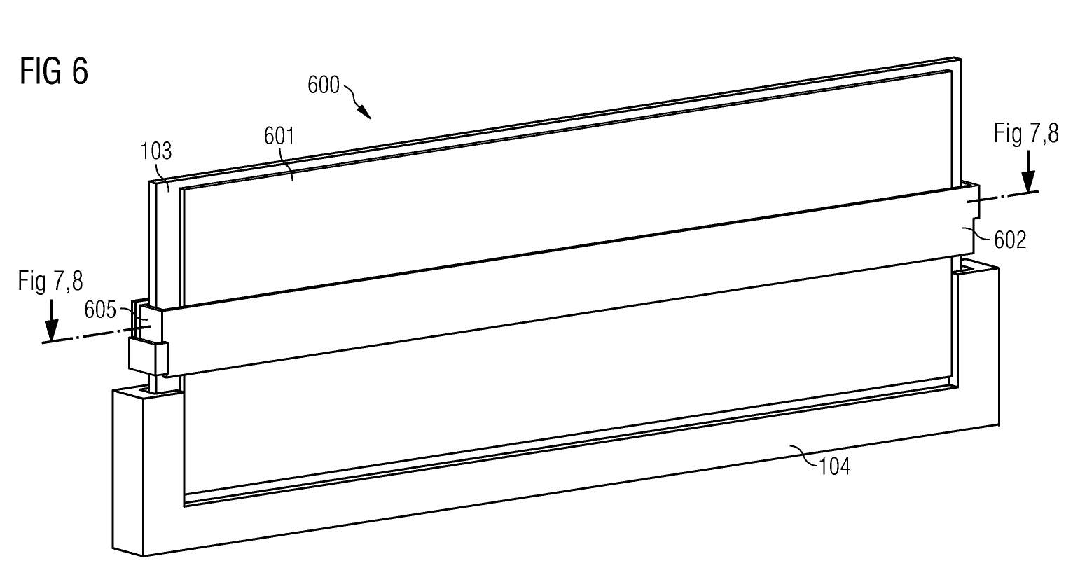

FIG. 6 depicts a heat sink 600 according to another embodiment of the present invention. The heat sink 600 includes a plate 601 that is pressed to a memory module 103. The memory module 103 is plugged into a slot 104.

The plate 601 is mounted to the memory module 103 with two clips 602. Each clip 602 includes a bar-shaped section. The bar-shaped section of each clip 602 may be approximately the length of long edge of the plate 601. The bar-shaped section is arranged parallel to the longer edges of the memory module 103. One clip 602 is arranged on each side of the memory module 103 respectively. Each clip 602 is arranged approximately in the center between the two longer edges of the memory module 103. The two clips 602 clasp around the shorter edges of the memory module 103 and the plate 601 to press the plate 601 to the memory module 103. The bar-shaped sections of the two clips 602 include hooks 605 arranged on both ends of the bar-shaped section of each clip 602 to clasp around the memory module 103 and the plates 601 and engage with the hooks 605 of the respective other clip 602 to lock both clips 602 together. A possible embodiment of a clip 602 with hooks 605 is shown in FIG. 10.

FIG. 10 depicts a schematic representation of two clips 1001. Each clip 1001 includes a bar-shaped section. Each clip 1001 includes two hooks 1002, 1003. The hooks 1002, 1003 are arranged on a first surface of the bar-shaped section of the clip 1001 and point in a direction perpendicular to the longitudinal direction of the bar-shaped section of the clip 1001. The clip 1001 is divided into two strips of equal height in the direction of the shorter edge of the bar-shaped section of the clip 1001. The first hook 1002 is arranged on the first strip. The second hook 1003 is arranged on the second strip. Each clip 1001 is symmetric regarding a rotation of 180° around a perpendicular axis through the center of the bar-shaped section of the clip 1001.

The second surface of each clip 1001 includes two grooves 1007. The grooves 1007 are arranged parallel to the two shorter edges of the bar-shaped section of the clip 1001. The grooves 1007 are arranged near the two shorter edges of the bar-shaped section of the clip 1001. One groove 1007 is arranged near the first shorter edge of the plate 1001. The other groove 1007 is arranged near the second shorter edge of the plate 1001.

The tip of each hook 1002, 1003 is bent towards the center of the bar-shaped part of the clip 1001 and includes a flange 1006 that points towards the bar-shaped part of the clip 1001. Two identical clips 1001 can be clipped together. The hooks 1002, 1003 of each clip 1001 clasp around a shorter edge of the other clip 1001. The flange 1006 of each hook 1002, 1003 of a first clip 1001 can snap in a groove 1007 of the second clip 1001, thereby fixing the two clips 1001 together.

The clips 1001 may be used as clips 602 in a heat sink 600, as shown in FIG. 6, to press the plate 601 to the memory module 103. The plate 601 of the heat sink 600 may be evenly flat. According to another embodiment, the plate 601 may be preformed as illustrated in FIGS. 2, 3 and described above, to provide an elevated contact pressing force between the plate 601 and the memory module 103 in designated regions of the surface of the memory module 103. The plate 601 may include a corrugation as shown in FIG. 2 to provide an elevated contact pressing force between the plate 601 and the memory module 103 in an area that is parallel to the shorter edge of the memory module 103 and arranged in the middle of the memory module 103 in the direction of the longer edge of the memory module 103. The plate 601 may also include a corrugation as described in FIG. 3 to provide elevated contact pressing forces in two areas of the surface of the memory module 103. The plates 601 may as well be preformed to provide another corrugation that is suitable to provide an elevated contact pressing force between the plate 601 and the memory module 103 in designated surface areas of the memory module 103 where outstanding heat sources are located.

According to another embodiment, an elevated contact pressing force between the plate 601 and the memory module 103 may be accomplished by preforming the clips 602. In this embodiment, the plate 601 of the heat sink 600 may be evenly flat. According to yet another embodiment, both the clips 602 and plate 601 may be preformed.

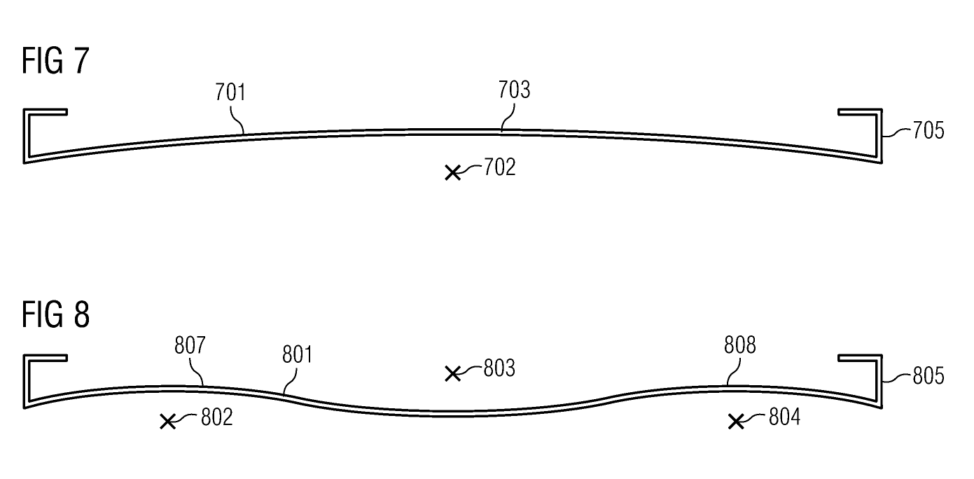

FIG. 7 depicts a sectional view of a preformed clip 701. In the sectional view of FIG. 7, the clip 701 is sliced on a plane that is parallel to the longer edge of the bar-shaped section of the clip 701 and perpendicular to the bar-shaped section of the clip 701. The clip 701 is bent around an axis 702 that is parallel to the shorter edge of the bar-shaped section of the clip 701. The axis 702 points out of the drawing plane of FIG. 7. Both ends of the bar-shaped section of the clip 701 include hooks 705 to mount the clip 701 together with another clip 701. The hooks 705 may for example be realized as disclosed above in the description of FIG. 10. If the clip 701 is used in a heat sink 600, the clip 701 causes an elevated contact pressing force between the plate 601 and the memory module 103 in a central section 703 of the clip 701. This may be advantageous if the central region of the memory module 103 includes a heat source that produces relatively higher amounts of heat.

The central section 703 of the clip 701 may be protruded over the ends of the bar-shaped section of the clip 701 by 0% to 10% of the length of the bar-shaped section of the clip 701. According to another embodiment the central section 703 of the clip 701 may be protruded over the ends of the bar-shaped section of the clip 701 by 10% to 20% of the length of the bar-shaped section of the clip 701. According to another embodiment the central section 703 of the clip 701 may be protruded over the ends of the bar-shaped section of the clip 701 by 20% to 40% of the length of the bar-shaped section of the clip 701.

FIG. 8 shows a sectional view of another embodiment of a preformed clip 801 that may be used as a clip 602 in a heat sink 600 as shown in FIG. 6. In the sectional view of FIG. 8, the clip 801 is sliced on a plane that is parallel to the longer edge of the bar-shaped section of the clip 801 and perpendicular to the bar-shaped section of the clip 801. The clip 801 shown in FIG. 8 is preformed to include a corrugation that provides elevated contact pressing forces between the plate 601 and the memory module 103 in two regions 807, 808 of the clip 801. Therefore, the clip 801 is bent around three axes 802, 803, 804 that are parallel to the shorter edge of the bar-shaped section of the clip 801. The axes 802, 803, 804 point out of the drawing plane of FIG. 8. The clip 801 includes hooks 805 arranged on both ends of the bar-shaped section of the clip 801. Two clips 801 may be locked together with the hooks 805. The hooks 805 may for example be realized as shown in FIG. 10. The hooks 805 may also be another kind of hooks that is suitable to lock two clips 801 together.

The amplitude of the corrugation of the clip 801 may be between 0% and 10% of the length of the bar-shaped section of the clip 801. According to another embodiment the amplitude of the corrugation of the clip 801 may be between 10% and 20% of the length of the bar-shaped section of the clip 801. According to another embodiment the amplitude of the corrugation of the clip 801 may be between 20% and 40% of the length of the bar-shaped section of the clip 801.

The clips 602 of the heat sink 600 may be preformed to include another shape than shown in FIGS. 7 and 8. The clips 602 may be preformed to any shape that provides an elevated contact pressing force in a designated region of the memory module 103.

In another embodiment, the heat sink 600 of FIG. 6 includes two plates 601 arranged on both sides of the memory module 103. A first surface of the first plate 601 is pressed to a first surface of the memory module 103. A first surface of the second plate 601 is pressed to a second surface of the memory module 103. The two clips 602 clasp around both plates 601, pressing them to the memory module 103. Both plates 601 may be preformed to be in a shape as shown in FIGS. 2 or 3 or to be in another shape. Both clips 602 may be preformed to include a shape as shown in FIGS. 7 or 8 or to include another shape.

While the foregoing is directed to embodiments of the present invention, other and further embodiments of the present invention may be devised without departing from the basic scope thereof, and the scope thereof is determined by the claims that follow.

What is claimed is:

1. An apparatus, comprising:
an electronic device, a clip and a plate of thermally conductive material, wherein a first surface of the plate is attached to a surface of the electronic device, wherein the clip is arranged on a second surface of the plate, wherein two ends of the clip clasp the electronic device and the plate at opposite edges of the electronic device, wherein the clip presses the plate to the electronic device.

2. The apparatus according to claim 1, wherein the clip comprises an essentially bar-shaped section that is arranged parallel to a longitudinal direction of the electronic device.

3. The apparatus according to claim 2, wherein the bar-shaped section of the clip is corrugated in a direction perpendicular to the second surface of the plate.

4. The apparatus according to claim 3, wherein the corrugation of the clip produces a corrugation of the plate.

5. The apparatus according to claim 3, wherein the clip is corrugated such that a central section of the clip is protruded towards the plate.

6. The apparatus according to claim 3, wherein the clip is corrugated such that two sections of the clip are protruded towards the plate.

7. The apparatus according to claim 1, wherein the clip material comprises spring steel.

8. The apparatus according to claim 1, wherein the plate material comprises one of the group of aluminum, copper, and graphite.

9. The apparatus according to claim 1, wherein the plate is corrugated in a direction perpendicular to the second surface of the plate.

10. The apparatus according to claim 9, wherein the corrugation is arranged at a central section of the electronic device.

11. The apparatus according to claim 9, wherein the plate is corrugated such that two sections of the plate are protruded towards the electronic device.

12. The apparatus according to claim 1, wherein a thermal interface material is provided between the first surface of the plate and the surface of the electronic device.

13. The apparatus according to claim 12, wherein the thermal interface material is a thermally conductive paste.

14. A heat sink plate for an electronic device, wherein the heat sink plate comprises a thermally conductive material, wherein a first surface of the heat sink plate is protruded for contacting a surface of the electronic device, wherein the heat sink plate is corrugated in a direction perpendicular to the first surface of the heat sink plate.

15. The heat sink plate according to claim 14, wherein the heat sink plate is corrugated such that a central section of the first surface of the heat sink plate is protruded.

16. The heat sink plate according to claim 14, wherein the heat sink plate is corrugated such that two sections of the first surface of the heat sink plate are protruded.

17. The heat sink plate according to claim 14, wherein the thermally conductive material comprises one of the group of aluminum, copper, and graphite.

18. The heat sink plate according to claim 14, wherein a second heat sink plate is provided, wherein the two heat sink plates comprise hooks, wherein the hooks are provided to clamp one heat sink plate to the other.

19. The heat sink plate according to claim 14, wherein the heat sink plate comprises a clip to press the plate to the electronic device.

20. The heat sink plate according to claim 19, wherein the clip comprises a U-shape, wherein the clip is provided to clasp around an edge of the plate and an edge of the electronic device.

21. The heat sink plate according to claim 20, wherein the clip is provided to clasp around a long edge of the plate and an edge of the electronic device.

22. The heat sink plate according to claim 20, wherein the clip is provided to clasp around a short edge of the plate and an edge of the electronic device.

23. The heat sink plate according to claim 19, wherein a second surface of the plate is opposed to the first surface of the plate, wherein an essentially bar-shaped section of the clip can be arranged on the second surface of the plate in a longitudinal direction of the plate, wherein on both ends of the bar-shaped section of the clip hooks are provided to clasp the electronic device and the plate such that the clip presses the plate to the electronic device.

24. The heat sink plate according to claim 19, wherein the clip material comprises spring steel.

25. The heat sink plate according to claim 14, wherein a thermal interface material is provided between the first surface of the heat sink plate and the surface of the electronic device.

26. The heat sink plate according to claim 25, wherein the thermal interface material is a thermally conductive paste.

27. A memory module comprising a clip and a plate of thermally conductive material, wherein a first surface of the plate is attached to a surface of the memory module, wherein the clip is arranged on a second surface of the plate, wherein two ends of the clip clasp the memory module and the plate at opposed edges of the memory module, wherein the clip presses the plate to the memory module.

28. An electronic system comprising a memory module, the memory module comprising a clip and a plate of thermally conductive material, wherein a first surface of the plate is attached to a surface of the memory module, wherein the clip is arranged on a second surface of the plate, wherein two ends of the clip clasp the memory module and the plate at opposed edges of the memory module, wherein the clip presses the plate to the memory module.

29. A heat sink plate for a memory module, wherein the heat sink plate comprises a thermally conductive material, wherein a first surface of the heat sink plate is protruded for contacting a surface of the memory module, wherein the heat sink plate is corrugated in a direction perpendicular to the first surface of the heat sink plate.

30. An electronic system comprising a memory module with a heat sink plate, wherein the heat sink plate comprises a thermally conductive material, wherein a first surface of the heat sink plate is protruded for contacting a surface of the memory module, wherein the heat sink plate is corrugated in a direction perpendicular to the first surface of the heat sink plate.
